(19) United States
(12) Patent Application Publication
(10) Pub. No.: US 2021/0031505 A1
(43) Pub. Date: Feb. 4, 2021

(54) TEMPERATURE REGULATED COMPONENTS HAVING COOLING CHANNELS AND METHOD

(71) Applicants: Luke Alan Boyer, Houston, TX (US); Christoph Wangenheim, Hemmingen (DE); Volker Peters, Wienhausen (DE); Gregory Folks, The Woodlands, TX (US); Walter James Myron, Houston, TX (US)

(72) Inventors: Luke Alan Boyer, Houston, TX (US); Christoph Wangenheim, Hemmingen (DE); Volker Peters, Wienhausen (DE); Gregory Folks, The Woodlands, TX (US); Walter James Myron, Houston, TX (US)

(73) Assignee: Baker Hughes, a GE company, LLC, Houston, TX (US)

(21) Appl. No.: 17/066,091

(22) Filed: Oct. 8, 2020

Related U.S. Application Data
(62) Division of application No. 15/385,319, filed on Dec. 20, 2016.

(51) Int. Cl. B33Y 80/00; B33Y 10/00; B33Y 30/00; F28F 7/02; F04C 15/00; F28F 13/06; F16C 37/00; H01L 23/46; F16C 33/66; F04C 2/107

(52) U.S. Cl. CPC B33Y 80/00; B33Y 10/00; B33Y 30/00; F28F 7/02; F04C 15/0096; F28D 2021/0028; F16C 37/00; H01L 23/46; F16C 33/6611; F04C 2/1075; F28F 13/06

(57) ABSTRACT

A tool having a temperature management arrangement includes a single piece unitary body, a channel within the body having a geometric discontinuity that forms a vortex chamber. A tool including a temperature management arrangement having a geometric discontinuity configured as a vortex chamber formed simultaneously with formation of a body. A method for producing a thermal management arrangement comprises additively growing the arrangement while selectively forming a channel in the arrangement, the channel comprising a geometric discontinuity formed as a vortex chamber.

### CROSS REFERENCE TO RELATED APPLICATIONS

This application is a divisional of U.S. application Ser. No. 15/385,319 filed Dec. 20, 2016, the disclosure of which is incorporated by reference herein in its entirety.

### BACKGROUND

Additive manufacturing is the process of printing a three-dimensional part as a single piece, using techniques such as Direct Metal Laser Melting (DMLM), Direct Metal Laser Sintering (DMLS), Direct Metal Deposition (DMD), Binder Jetting, or electron beam melting/fabrication, for example. Each process builds solid parts from three dimensional Computer Aided Design (CAD) models and allows construction of heretofore impossible one piece configurations. Additive manufacturing processes are known to the art and require no specific discussion in connection with this disclosure.

### SUMMARY

A tool having a temperature management arrangement including a unitary body, a channel within the body having a geometric discontinuity.

A tool including a temperature management arrangement having a seal-less channel formed simultaneously with formation of a body.

A method for producing a thermal management arrangement including additively growing the arrangement while selectively forming a seal-less channel in the arrangement.

### BRIEF DESCRIPTION OF THE DRAWINGS

The following descriptions should not be considered limiting in any way. With reference to the accompanying drawings, like elements are numbered alike:

FIG. 1 is a perspective view of a heat sink embodiment as disclosed herein;

FIG. 2 is a schematic representation of a vortex chamber as disclosed herein;

FIG. 3 is a perspective view of a mud motor rotor having channels therein;

FIG. 4 is an end view of a mud motor rotor having latticed channels therein;

FIG. 5 is an end view of a mud motor stator having channels therein;

FIG. 6 is an end view of another mud motor stator having channels therein;

FIG. 7 is an end view of another mud motor stator having channels therein;

FIG. 8 is an end view of another mud motor stator having channels herein;

FIG. 9 is an end view of another mud motor stator having a latticed channel herein;

FIG. 10 is a perspective view of a stator having a channel with vortex chamber;

FIG. 11 is an end view of a stator with a loop connecting vortex chambers;

FIG. 12 is a perspective view of a bearing assembly having cooling channels therein;

FIG. 13 is a perspective view of an electronic frame assembly having cooling channels therein; and

FIG. 14 is an end view of FIG. 13.

### DETAILED DESCRIPTION

A detailed description of one or more embodiments of the disclosed apparatus and method are presented herein by way of exemplification and not limitation with reference to the Figures.

Through additive manufacturing methods, the inventors hereof have configured tools such as those illustrated in the Figures that benefit from superior thermal regulation capability, greater strength and resultantly superior service life. These benefits come from controlled fluid motion characteristics pursuant to channel geometry heretofore impossible at least in single piece configurations without seals. Characteristics implicated are turbulent and laminar flows, dwell times, surface area contact variations over a channel, phase changes, and others. The configurations shown further allow for functional unit changes (such as significantly higher heat generating processing equipment) to previously accepted limits due to thermal production because of the enhanced thermal management capability of configurations as taught herein.

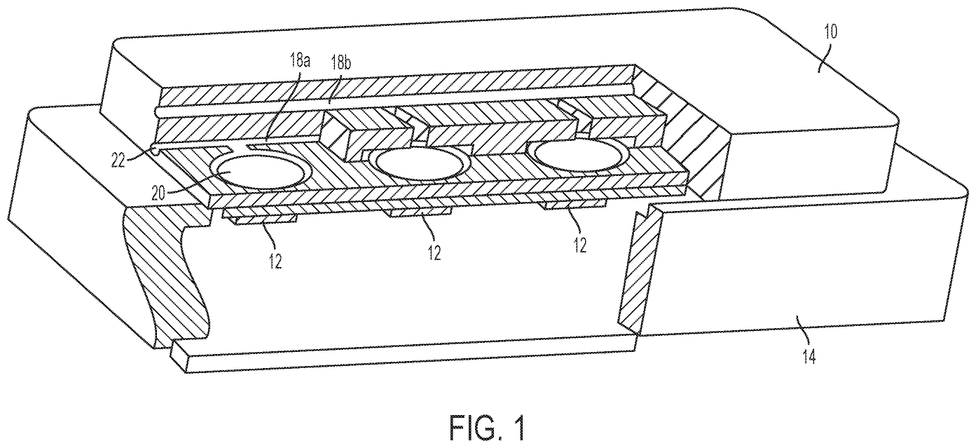

Referring to FIG. 1, a thermal management arrangement 10 having a unitary, integrally formed body 11 is illustrated in contact with a heat source 12 which may be mounted in a frame 14. The body may be connected to other bodies or conduits for fluid flow and that connection might contain a seal but the body 11 itself is seal-less in that no seals are extant in the body. The thermal management arrangement 10 is constructed via additive manufacturing processes from materials such as aluminum, copper and alloys of each, stainless steels and titanium, for example. As illustrated in FIG. 1, the thermal management arrangement is a heat sink, which is configured with seal-less fluid flow channels 18 (in embodiments from 0.125 to 1 inch in diameter, for example) one or more of which is configured with one or more geometric discontinuities 20. The term geometric discontinuities as used herein is intended to refer to forms that do not follow the general shape of the rest of the channel 18. Such geometric discontinuities may in some embodiments create tortuosity in the channel. More specifically, and by way of example, an inlet portion 22 of a channel 18 in FIG. 1 is cylindrically shaped but that form changes at geometric discontinuity 20 in the form of a vortex chamber. The geometric discontinuity in this case provides a much larger flow area (volume in a single feature, a spread of meandering channels, etc.) than does the inlet portion 22, which as will be understood, changes the thermal transfer characteristics of the channel 18 and facilitates an individual transfer geometry for nonequal temperature distribution over a particular tool. A vortex chamber is but one example of a geometric discontinuity contemplated herein with embodiments presenting larger and smaller flow areas for differing purposes and differing thermal diffusion directions. It is noted that a vortex chamber offers a high heat transfer at a comparatively low pressure drop making them particularly advantageous for some iterations. As will be understood, traditionally manufacturing a channel with a geometric discontinuity as defined herein would be at best difficult in the prior art and if even possible for the contemplated shape almost invariably would require at least two structural pieces sealed together with a seal.

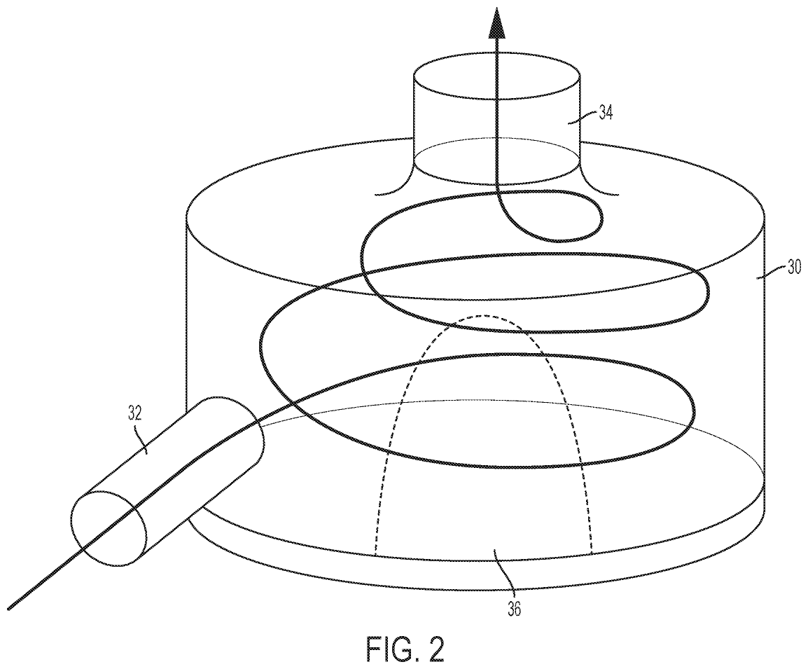

In FIG. 1, three geometric discontinuities 20 are illustrated being supplied by fluid through an inlet portion 22 of channel 18a. In the figure, each of these discontinuities 20 discharges fluid through channel 18b. It will be appreciated that each of the discontinuities is positioned directly adjacent a heat source 12 to enhance thermal diffusion to or from the fluid within the channels 18. While the discontinuities may simply be larger volumetric sections of the channel that cause fluid velocity to slow (and perhaps to encourage phase change), they also may be specifically configured as vortex chambers to generate stable vortices of flowing fluid for increased thermal transfer. To enhance understanding of the vortex chambers contemplated herein, reference will be made to FIG. 2. FIG. 2 is a schematic representation of a vortex chamber and is not intended to be a limiting disclosure but one that will make understanding of the vortex chamber embodiment of a geometric discontinuity clearer for the reader. The schematically illustrated vortex chamber is of cylindrical body 30 in FIG. 2 though conical, frustoconical, hyperbolic, spiral cyclone-like forms, other geometric shapes and even other geometric cross sectional tubular shapes may be substituted with appropriate consideration of the effects of flow patterns and boundary layers in such shapes. An inlet 32 is disposed to provide an inflow of fluid at a near tangent to the circular cross section of the body 30. Introduction of fluid at an angle such as shown will initiate a spiral flow resulting in a stable vortex inside the body 30. In embodiments, the fluid inlet 32 may comprise a slit nozzle, conical nozzle, orifice, or other elements to increase fluid speed entering the chamber 20. Exit 34 on the other hand is at a central position relative to body 30 which also helps support the stable vortex as desired. In some embodiments, additional structure 36 (illustrated in broken lines both because it is inside of body 30 and because it is optional) may be disposed within the vortex of fluid to increase thermal diffusion.

It should be understood then that such geometric discontinuities may be located anywhere within a thermal management channel and will be particularly desirably placed in areas where increased thermal management would be beneficial. For example, creating a greater turbulence, contact area or dwell time in areas of a heat producing tool where heat production is highest would be desirable and functionally helpful. Of course, thermal load being supplied in reverse may also be helpful in certain situations such as for tools with components exposed to extreme cold that work better if maintained as a higher relative temperature.

Through additive manufacturing methods, channels 18 having the attributes discussed may be constructed as single piece structures. No sealing consideration will be needed because there is no need to form, for example, cast separate parts and then seal them to one another. The avoidance of any kind of breach in the structure (seals, plugs, etc.) improves reliability and long service life.

In addition, it is further contemplated herein that through the additive manufacturing methods, valves may be placed in line with the channels 18. This allows greater design opportunities using interconnected circuits of channels that may be used or cordoned off as needed. In a particular embodiment, the valve is a bimetal valve that automatically shifts position based upon thermal load to which it is exposed. Such valves may be additively manufactured in the channel as the channel itself is being formed. Again, no seals, no structural weakening.

While FIG. 1 illustrates a heat sink arrangement, it will be appreciated that the channels with geometric discontinuities are applicable to any construction that requires thermal management. This includes downhole tools such as mud motors (stators and rotors) and other tools requiring such temperature management

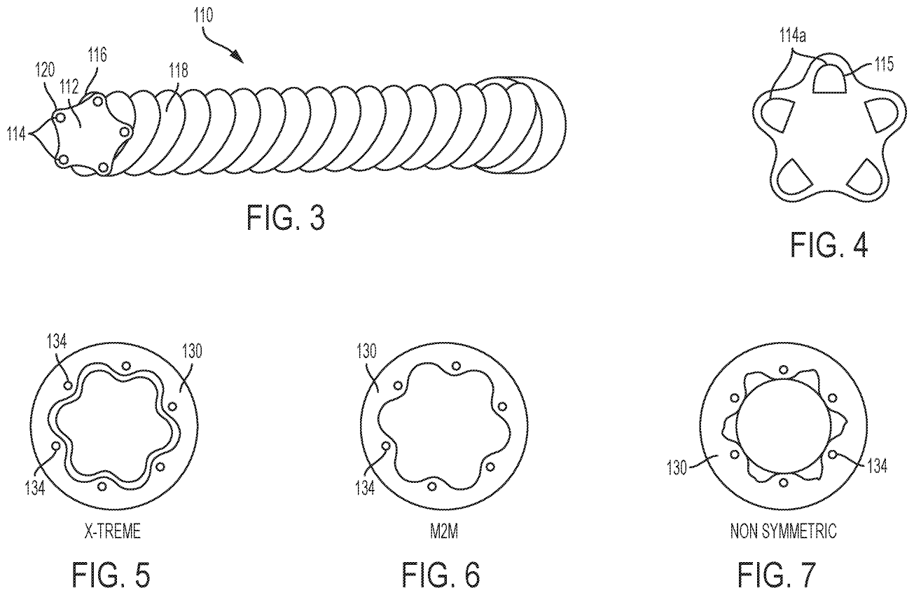

Referring to FIG. 3a perspective view of a rotor 110, such as for example a mud motor rotor is illustrated schematically. The rotor outwardly appears as do all such rotors but at an end 112 thereof, one or more cooling channels 114 are visible. The channels 114 are to be fluidly connected to a source of fluid whether that be gas or liquid and which source may be passive or active such that fluid may be pumped through the channels 114 or may be allowed to passively occupy the channels 114 and flow based solely upon a pressure differential existing from one end of the mud motor to the other. The degree of heat transfer will change based upon the fluid movement, properties of the particular fluid and the heat transfer capability of the particular channel. The channels 114 are configured, dimensioned and positioned to be subject to the greatest temperature loading and hence to have the greatest effect on the rotor 110 when fluid is flowed through the channels 114. It is contemplated that the channels 114 may be cooling channels but is also contemplated that the channels may be heating channels depending upon the ultimate temperature gradient in which the rotor 110 is to operate. The channels 114 are positioned to take advantage of maximum heat transfer capability relative to the lobes 116 of the rotor 110. It will be appreciated that the lobes 116 are proud of a root diameter 118, and the lobes are helical in three dimensional space. The channels 114 then, as shown in end 112, must progress in a helical pattern staying within the lobes 116 as the lobes rotate about the rotor 10. As one of skill in the art will recognize, such a construction is not possible with conventional subtractive manufacturing methods but is possible through the use of additive manufacturing methods. Further, any of the geometric discontinuities described above are equally applicable to this and the embodiments below.

Since heat transfer (in either direction depending upon embodiment) is a particular interest, it is desirable to place the channels 114 close to a surface 120 of the rotor 110. Moreover, the channel 114 may have a range of diameters of from something small such as ⅛ inch to a diameter more closely mimicking a curvature of the lobe itself. The larger the diameter of the channel, the less the structural integrity of the rotor but the greater the heat transfer capacity. In an embodiment, see FIG. 4, where a shape of the channel 114a closely matches a shape of the lobe 116 or otherwise occupies significant portion of the structural area of the rotor, some embodiments will benefit from adding web structures 115 within the channel 114a for strength. Similar to the disclosure above with respect to a rotor, a stator can also be formed having the benefits noted above. Referring to FIGS. 5-7 different types of stators 130 (rubber lined, metal to metal, non-symmetric) are provided with channels 134. The channels 134 are positioned in the lobes 36 of the stators 130 similarly to the positioning in the rotor embodiments discussed above and with the same heat transfer and structural considerations.

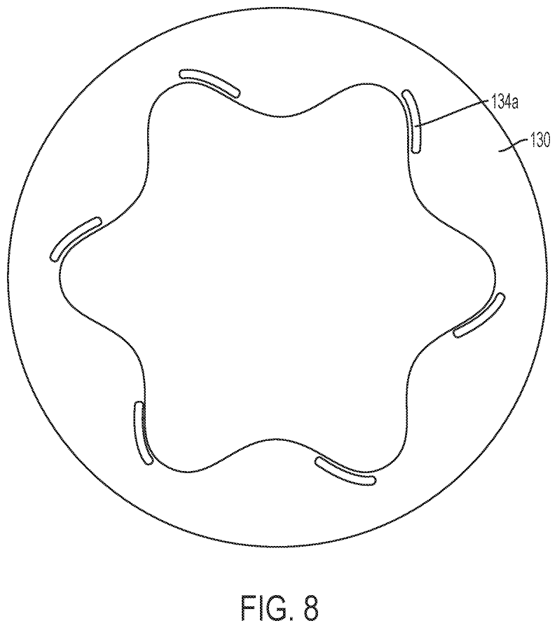

Referring to FIG. 8, a different type of channel is illustrated in a schematic stator. The channel 134a cross section is not circular but rather oval or kidney shaped. Such shapes are impossible to achieve in traditional manufacturing without either the addition of sealing structures between at least two components that might be subtractively machined or cast and then joined to form the channel but are possible using additive manufacturing techniques. Such shapes may be configured to promote turbulent flow of fluid for enhanced heat transfer.

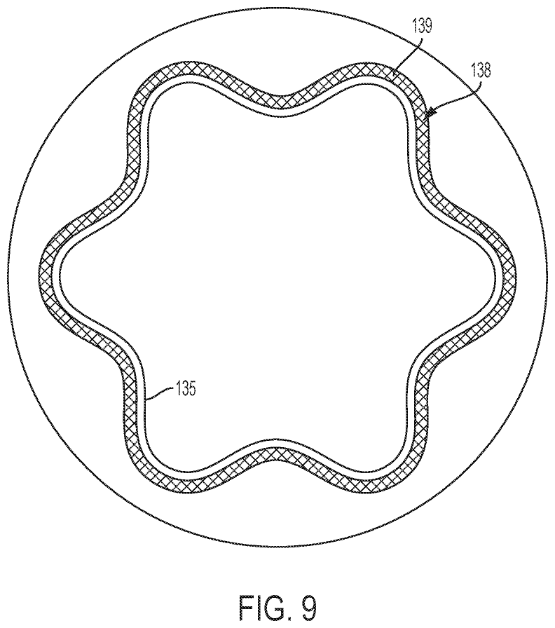

Referring to FIG. 9, it is also contemplated to provide for heat transfer flow along the entirety of the tribological surfaces 135 of the stator with a channel 138 that extends entirely about the tribological surface 135 as shown in FIG. 9. It is to be understood however that this channel 138 could also be broken up into a number of part channels that when viewed together will substantially address the tribological surface 135. Whether in a single channel 138 or a number of them where structural integrity of the stator itself would be imperiled, a lattice structure 139 or otherwise porous structure (i.e. a structure through which a fluid media may move) may be added to ensure that the surface 135 of the stator stays in place. It will be understood that the lattice structure may be a plurality of radially oriented ribs, a plurality of intersecting ribs, a honeycomb configuration, etc. It is also to be understood that the concept applies equally well to rotor embodiments or other tools requiring thermal management.

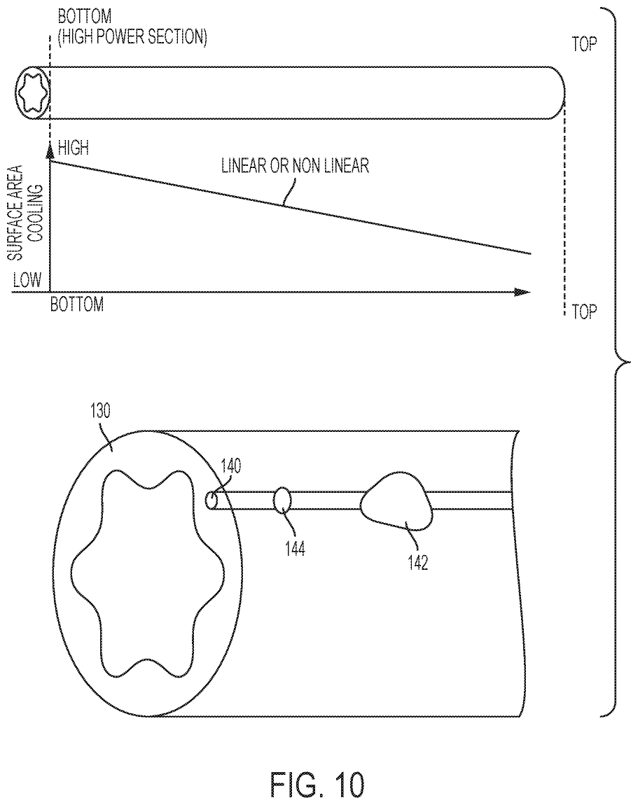

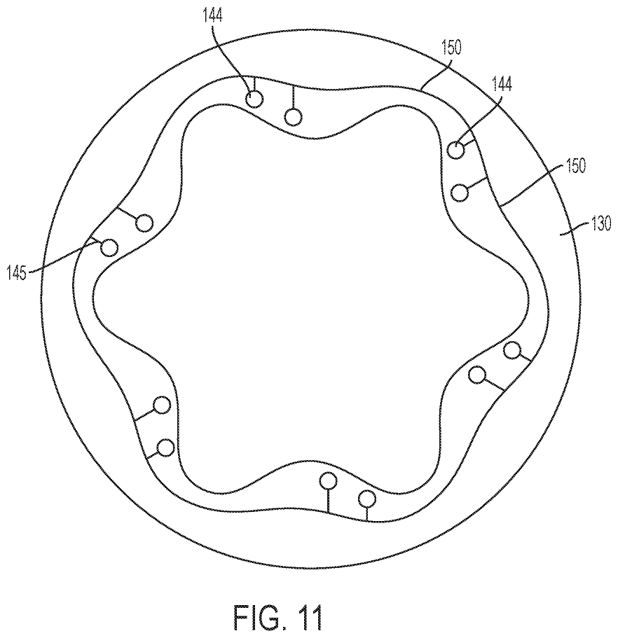

Referring to FIG. 10, a stator 130 embodiment employs a channel 140 that further includes one or more geometric discontinuities 142 as discussed above. In an embodiment where the discontinuity is a vortex chamber, the vortex chamber 142 enhances turbulence and surface area for heat transfer in a manner similar to that discussed with respect to the heat sink of FIG. 1. In embodiments, the channel 140 will intersect the vortex chamber 142 such that fluid flowing through the channel 140 will tangentially enter the vortex chamber 142 thereby initiating a stable laminar vortex therein. In some embodiments, it may be desirable to add structure in the center of the vortex chamber 142 for even greater thermal transfer. Again, such configurations are possible only by employing an additive manufacturing process.

In a related embodiment, it may be desirable to include a valve 144 such as the bimetal valve discussed above that will open and close automatically in response to heat load. In an embodiment, the valve is AM printed directly into the channel 140.

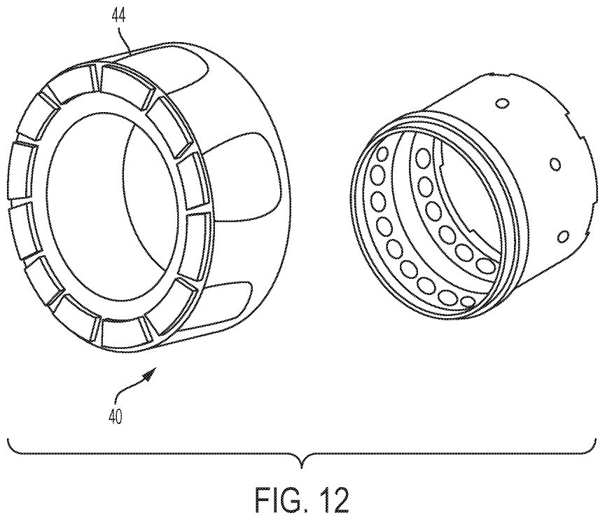

Referring to FIG. 11, an embodiment that uses a loop conduit 150 is illustrated. The loop conduit links individual geometric discontinuities 144 together through inlet 145 for fluid supply and egress. The egress conduit is not shown as it would be above or below the plane of the drawing although it would look similar to the inlet 145. These chambers may in some embodiments may be configured to allow tangential fluid flow to generate a stable vortex therein as discussed above. As illustrated there are two discontinuities 144 in each lobe of the stator 130 but of course more or fewer, larger or smaller and in and relative position may be employed for a given iteration. In the event the discontinuities of this embodiment are to be vortex chambers then the inlet 145 may advantageously be positioned to assist in vortex formation within the chamber as discussed hereinabove.

In both rotor and stator applications, and indeed in any application requiring differential heat transfer to or from a working surface such as the higher heat load at one end of a rotor or stator (lower end) in a mud motor or in any other similarly burdened construction, the channels may be provided with unique geometries along their own lengths. For example, a higher surface area in a higher differential temperature area of the tool such that greater or lesser heat transfer will occur in particular locations of a specific tool to be temperature managed is possible in accordance with the teachings hereof.

Referring to FIG. 12, a bearing embodiment is illustrated. Bearings suffer from heat generation due primarily to frictional inputs but heat may also be exacerbated by environmental heat load as well. The hotter a bearing runs, the shorter its service life will be. Accordingly, the inventors hereof set out to create bearings that can be used in very high heat environments (whether generated, environmentally exposed or both) and still provide for a long service life. This is accomplished by configuring heat transfer channels within the bearing itself similar to the embodiments discussed above. FIG. 12 is a schematic perspective view of an embodiment of a bearing 160 having cooling channels 164 running adjacent contact areas of the bearing 160.

Positioning, configuration and dimension of channels 164 for bearing cooling duties include the same considerations as disclosed above. Additionally, it is contemplated that the material defining the channels 164 that is near to a wear surface of the bearing may be configured as a more porous material constitution permeable to lubricants in the cooling fluid, such that in an embodiment, the lubricants will migrate through the porous material thereby applying lubricant to the wear surfaces.

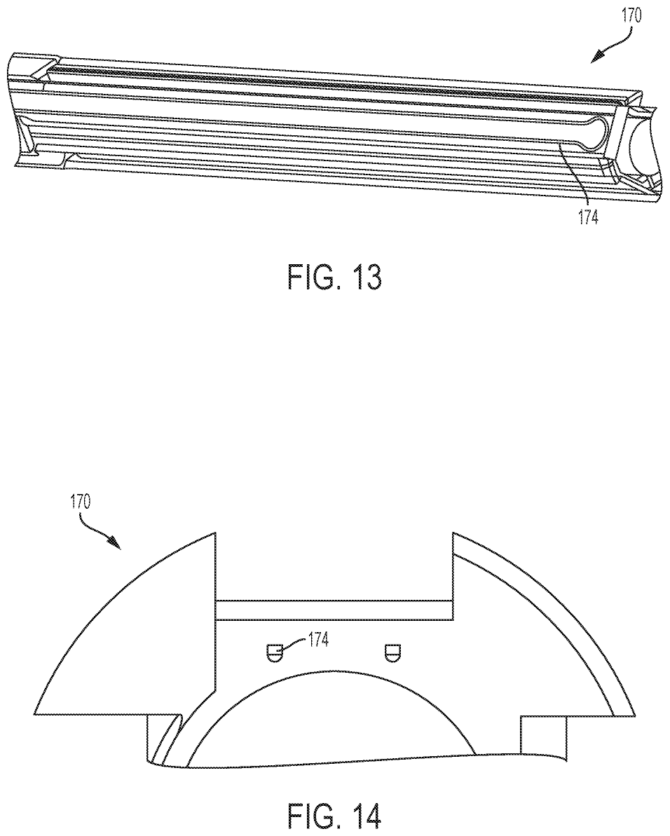

Referring to FIG. 13, an electrical frame assembly 170 is illustrated. The frame 170 is configured to support electrical components such as batteries, processors, etc. In another embodiment of the foregoing concepts, thermal transfer channels 174 are provided in the frame 170 (see FIG. 14 for entry of channels 174 to frame 170). Again, due to the capabilities of additive manufacturing rather than subtractive manufacturing, positioning, configuring and conditioning of the channels 174 may be particularly optimized for the heat source and frame needing to be cooled or vice versa. In an embodiment, as illustrated, the channels 174 are looped around the prospective heat source and in close proximity thereto for maximum heat transfer to the fluid in the channel 174. For each of the foregoing embodiments, the fluid can be a heat transfer fluid in a liquid or gaseous form including such as for example water, alcohol/water mixture, mineral oil, synthetic oil, ammonia to help thermally manage the bulk structure, but it should also be understood that in cases where the channels do not simply loop back to a starting point but rather end at other locations, the channels can also be employed to convey fluid to the remote location. Accordingly, the channels can be both heat transfer conduits and material conveyance conduits. Where material is to be conveyed, it may be a lubricant (e.g., low viscosity oils, or carbon nano-structure containing fluids), sand, gravel or other proppants, abrasives, drilling particles, damping fluids, etc.). Also to the extent sensors are to be fluid conveyed, the channels disclosed herein may be sized and configured for passage of such sensors. Further, depending upon the geometric path of a particular channel, it may also be possible to dispose a conductor in the channel after manufacture or the conductor may be manufactured in place in the channel if desired.

Further disclosed is a method for producing a thermal management arrangement comprising additively growing the arrangement while selectively forming a seal-less channel in the arrangement the channel optionally including a geometric discontinuity. The method can be carried out using any known or to be created additive manufacturing methodologies such that the channel may be formed according to a program in a layer by layer deposition. This allows the channel to have features including but not limited to geometric discontinuities that cannot be created using a subtractive manufacturing method.

### Embodiment 1

A tool having a temperature management arrangement including a unitary body, a channel within the body having a geometric discontinuity.

### Embodiment 2

The arrangement as in any prior embodiment further comprising a fluid disposed within the channel.

### Embodiment 3

The arrangement as in any prior embodiment wherein the fluid is at a first temperature at an inlet to the seal-less channel of the body and at a second temperature at an outlet of the seal-less channel of the body.

### Embodiment 4

The arrangement as in any prior embodiment wherein the first temperature is different from the second temperature.

### Embodiment 5

The arrangement as in any prior embodiment wherein the channel further includes a valve formed in the channel.

### Embodiment 6

The arrangement as in any prior embodiment wherein the body is a heat sink.

### Embodiment 7

The arrangement as in any prior embodiment wherein the geometric discontinuity is a vortex chamber.

### Embodiment 8

The arrangement as in any prior embodiment wherein the vortex chamber has a centrally located exit.

### Embodiment 9

The arrangement as in any prior embodiment wherein the vortex chamber includes an inlet that supplies fluid to the vortex chamber at an angle.

### Embodiment 10

The arrangement as in any prior embodiment wherein the angle is selected to facilitate formation of a vortex in the vortex chamber.

### Embodiment 11

The arrangement as in any prior embodiment wherein the angle is about tangent to the vortex chamber.

### Embodiment 12

The arrangement as in any prior embodiment wherein the inlet further includes a nozzle.

### Embodiment 13

The arrangement as in any prior embodiment wherein the nozzle is a slit nozzle.

### Embodiment 14

The arrangement as in any prior embodiment wherein the discontinuity includes an additional structure centrally of the vortex chamber.

### Embodiment 15

The arrangement as in any prior embodiment wherein the heat sink absorbs heat from electronic devices, sensors and transducers

### Embodiment 16

The arrangement as in any prior embodiment wherein the tool body is a rotor of a mud motor.

### Embodiment 17

The arrangement as in any prior embodiment wherein the tool body is a stator of a mud motor.

### Embodiment 18

The arrangement as in any prior embodiment wherein the tool body is a bearing.

### Embodiment 19

The arrangement as in any prior embodiment wherein the tool body is an electronics frame.

### Embodiment 20

The arrangement as in any prior embodiment wherein the seal-less channel includes a loop conduit.

### Embodiment 21

A tool including a temperature management arrangement having a seal-less channel formed simultaneously with formation of a body.

### Embodiment 22

The arrangement as in any prior embodiment wherein the seal-less channel ranges in diameter from 0.125 to 1 inch.

### Embodiment 23

The arrangement as in any prior embodiment wherein the seal-less channel is helical.

### Embodiment 24

The arrangement as in any prior embodiment wherein the seal-less channel is oval or kidney shaped in cross section.

### Embodiment 25

The arrangement as in any prior embodiment wherein the seal-less channel includes a lattice work therein.

### Embodiment 26

A method for producing a thermal management arrangement including additively growing the arrangement while selectively forming a seal-less channel in the arrangement.

The use of the terms “a” and “an” and “the” and similar referents in the context of describing the invention (especially in the context of the following claims) are to be construed to cover both the singular and the plural, unless otherwise indicated herein or clearly contradicted by context. Further, it should further be noted that the terms “first,” “second,” and the like herein do not denote any order, quantity, or importance, but rather are used to distinguish one element from another. The modifier “about” used in connection with a quantity is inclusive of the stated value and has the meaning dictated by the context (e.g., it includes the degree of error associated with measurement of the particular quantity).

The teachings of the present disclosure may be used in a variety of well operations. These operations may involve using one or more treatment agents to treat a formation, the fluids resident in a formation, a wellbore, and/or equipment in the wellbore, such as production tubing. The treatment agents may be in the form of liquids, gases, solids, semi-solids, and mixtures thereof. Illustrative treatment agents include, but are not limited to, fracturing fluids, acids, steam, water, brine, anti-corrosion agents, cement, permeability modifiers, drilling muds, emulsifiers, demulsifiers, tracers, flow improvers etc. Illustrative well operations include, but are not limited to, hydraulic fracturing, stimulation, tracer injection, cleaning, acidizing, steam injection, water flooding, cementing, etc.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited.

What is claimed is:

1. A tool having a temperature management arrangement comprising:
a single piece unitary body;
a channel within the body having a geometric discontinuity that forms a vortex chamber.

2. The arrangement as claimed in claim 1 further comprising a fluid disposed within the channel.

3. The arrangement as claimed in claim 2 wherein the fluid is at a first temperature at an inlet to the channel of the body and at a second different temperature at an outlet of the channel of the body.

4. The arrangement as claimed in claim 1 wherein the channel further includes a valve formed in the channel.

5. The arrangement as claimed in claim 1 wherein the vortex chamber has a centrally located exit.

6. The arrangement as claimed in claim 1 wherein the vortex chamber includes an inlet that supplies fluid to the vortex chamber at an angle.

7. The arrangement as claimed in claim 6 wherein the angle is about tangent to the vortex chamber.

8. The arrangement as claimed in claim 1 wherein the vortex chamber includes an inlet, the inlet includes a nozzle.

9. The arrangement as claimed in claim 1 wherein the discontinuity includes an additional structure centrally of the vortex chamber.

10. The arrangement as claimed in claim 1 wherein the tool body is a rotor of a mud motor.

11. The arrangement as claimed in claim 1 wherein the tool body is a stator of a mud motor.

12. The arrangement as claimed in claim 1 wherein the tool body is a bearing.

13. The arrangement as claimed in claim 1 wherein the tool body is an electronics frame.

14. The arrangement as claimed in claim 1 wherein the channel includes a loop conduit.

15. A tool including a temperature management arrangement having a channel having a geometric discontinuity configured as a vortex chamber formed simultaneously with formation of a body.

16. The arrangement as claimed in claim 15 wherein the channel ranges in diameter from 0.125 to 1 inch.

17. The arrangement as claimed in claim 15 wherein the channel is helical.

18. The arrangement as claimed in claim 15 wherein the channel is oval or kidney shaped in cross section.

19. The arrangement as claimed in claim 15 wherein the channel includes a lattice work therein.

20. A method for producing a thermal management arrangement comprising:
additively growing the arrangement while selectively forming a channel in the arrangement, the channel comprising a geometric discontinuity formed as a vortex chamber.
